(19) United States
(12) Patent Application Publication
(10) Pub. No.: US 2026/0051847 A1
(43) Pub. Date: Feb. 19, 2026

(54) Balance Restoring Phase Noise Filter for Complementary Oscillator Circuitry

(71) Applicant: Apple Inc., Cupertino, CA (US)

(72) Inventor: Omar E. Elaasar, San Diego, CA (US)

(21) Appl. No.: 19/086,673

(22) Filed: Mar. 21, 2025

Related U.S. Application Data
(60) Provisional application No. 63/683,653, filed on Aug. 15, 2024.

(51) Int. Cl. H03B 5/12

(52) U.S. Cl. CPC H03B 5/1212

(57) ABSTRACT

Oscillator circuitry is provided that includes a pair of n-type transistors coupled to a first tail node, a pair of p-type transistors coupled to a second tail node, a first tail coil coupled to the first tail node, a first filter coil magnetically coupled to the first tail coil, and a first tunable capacitor coupled across opposing terminals of the first filter coil. The oscillator circuitry can further include a second tail coil coupled to the second tail node, a second filter coil magnetically coupled to the second tail coil, a second tunable capacitor coupled across opposing terminals of the second filter coil, and a tunable differential capacitor coupled between the first tunable capacitor and the second tunable capacitor. The first and second tunable capacitors can be configured to restore a balance between the pair of n-type transistors and pair of p-type transistors.

This application claims the benefit of U.S. Provisional Patent Application No. 63/683,653, filed Aug. 15, 2024, which is hereby incorporated by reference herein in its entirety.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless communications circuitry in the wireless communications circuitry uses the antennas to receive and transmit radio-frequency signals.

The wireless communications circuitry can include a transceiver having one or more mixers. A mixer in the transmit path can be used to modulate signals from a baseband frequency to a radio frequency, whereas a mixer in the receive path can be used to demodulate signals from the radio-frequency to the baseband frequency. Mixers receive clock signals generated from local oscillator circuitry. It can be challenging to design satisfactory local oscillator circuitry for an electronic device.

### SUMMARY

An aspect of the disclosure provides oscillator circuitry that includes: a pair of n-type transistors coupled to a first tail node; a pair of p-type transistors coupled to a second tail node; output terminals coupled between the pair of n-type transistors and the pair of p-type transistors, an oscillating signal being produced at the output terminals; a first tail coil coupled to the first tail node; a first filter coil magnetically coupled to the first tail coil; and a first tunable capacitor coupled across opposing terminals of the first filter coil. The oscillator circuitry can further include, a second tail coil coupled to the second tail node, a second filter coil magnetically coupled to the second tail coil, a second tunable capacitor coupled across opposing terminals of the second filter coil, and a tunable differential capacitor coupled between the first tunable capacitor and the second tunable capacitor. The first tail coil and the first filter coil can form part of a one-to-one impedance transformer.

An aspect of the disclosure provides oscillator circuitry that includes a pair of cross-coupled n-type transistors coupled to a first tail node, a pair of cross-coupled p-type transistors coupled to a second tail node, a first 1:1 impedance transformer coupled to the first tail node, and a first tunable single-ended capacitor coupled to the first 1:1 impedance transformer. The oscillator circuitry can further include a second 1:1 impedance transformer coupled to the second tail node, a second tunable single-ended capacitor coupled to the second 1:1 impedance transformer, and a tunable differential capacitor having a first terminal coupled to the first tunable single-ended capacitor and having a second terminal coupled to the second tunable single-ended capacitor. The pair of cross-coupled n-type transistors and the pair of cross-coupled p-type transistors can exhibit unbalanced characteristics, and the first tunable single-ended capacitor and second tunable single-ended capacitors can be configured to restore a balance between the pair of cross-coupled n-type transistors and the pair of cross-coupled p-type transistors.

An aspect of the disclosure provides circuitry that includes a pair of n-type transistors coupled to a first tail node, a pair of p-type transistors coupled to a second tail node, wherein the pair of n-type transistors and the pair of p-type transistors exhibit unbalanced characteristics, a load inductor coupled between the pair of n-type transistors and the pair of p-type transistors, a load capacitor coupled in parallel with the load inductor, and a phase noise filter configured to reduce a phase noise of the circuitry and coupled between the first and second tail nodes. The phase noise filter includes at least first and second single-ended capacitors configured to restore a balance between the pair of n-type transistors and pair of p-type transistors. The phase noise filter can further include a first coil coupled in parallel with the first single-ended capacitor, a second coil coupled in parallel with the second single-ended capacitor, a third coil coupled to the first tail node and magnetically coupled to the first coil, a fourth coil coupled to the second tail node and magnetically coupled to the second coil, and a differential capacitor having a first terminal coupled to a node between the first coil and the first single-ended capacitor and having a second terminal coupled to a node between the second coil and the second single-ended capacitor. The first coil and the third coil can be part of a first 1:1 impedance transformer with identical and overlapping footprints. The second coil and the fourth coil can be part of a second 1:1 impedance transformer with identical and overlapping footprints.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having oscillator circuitry in accordance with some embodiments.

FIG. 3 is a diagram of illustrative complementary oscillator circuitry having a phase noise filter in accordance with some embodiments.

FIG. 4 is a circuit diagram showing an illustrative implementation of the complementary oscillator circuitry of FIG. 3 in accordance with some embodiments.

FIG. 5 is a plot of phase noise as a function of differential tail capacitance when the n-side and p-side components are unbalanced.

FIG. 6 is a plot of phase noise as a function of differential tail capacitance when the n-side and p-side components are optimized using balance restoring capacitors to reduce phase noise in accordance with some embodiments.

FIG. 7 is a flowchart of illustrative steps for determining capacitance values for a phase noise filter of the type shown in FIGS. 3 and 4 in accordance with some embodiments.

FIG. 8 is a table of illustrative capacitance values for a phase noise filter configured to operate at various frequencies in accordance with some embodiments.

### DETAILED DESCRIPTION

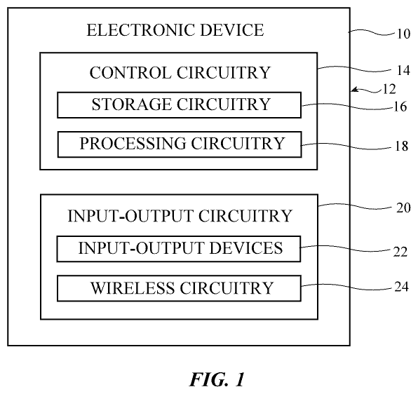

An electronic device such as electronic device 10 of FIG. 1 may be provided with wireless circuitry. The wireless circuitry can include one or more mixers and oscillator circuitry configured to generate oscillating signals or clock signals that are supplied to the one or more mixers. The oscillator circuitry can be a voltage controlled oscillator (VCO) having one or more inductors and a tunable capacitor. Such type of voltage controlled oscillator is sometimes referred to as an “LC” (inductor-capacitor) VCO. An LC VCO can include both n-type transistors and p-type transistors; such type of LC VCO is sometimes referred to as a “complementary” LC VCO. The n-type transistors can be coupled to a first power supply line via a first tail coil, whereas the p-type transistors can be coupled to a second power supply line via a second tail coil.

In accordance with an embodiment, a complementary LC VCO can be provided with a phase noise filter or resonator that is coupled between the n-type and p-type transistors. The phase noise filter can include a first filter coil magnetically coupled to the first tail coil (collectively forming a first 1:1 impedance transformer), a second filter coil magnetically coupled to the second tail coil (collectively forming a second 1:1 impedance transformer), a differential programmable capacitor coupled between the first and second filter coils, a first single-ended programmable capacitor coupled in parallel with the first filter coil, and a second single-ended programmable capacitor coupled in parallel with the second filter coil. The first and second tail coils can be considered to be part of the phase noise filter. The phase noise filter is thus sometimes referred to as a phase noise “tail” filter. The single-ended programmable capacitors can be configured as balance restoration components to individually optimize the impedances at the n-type transistors and the p-type transistors to minimize flicker noise from both sides. Doing so can be technically advantageous by providing improved overall flicker noise reduction.

Electronic device 10 of FIG. 1 can include such complementary LC VCO with an improved phase noise tail filter and may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or THF bands), etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

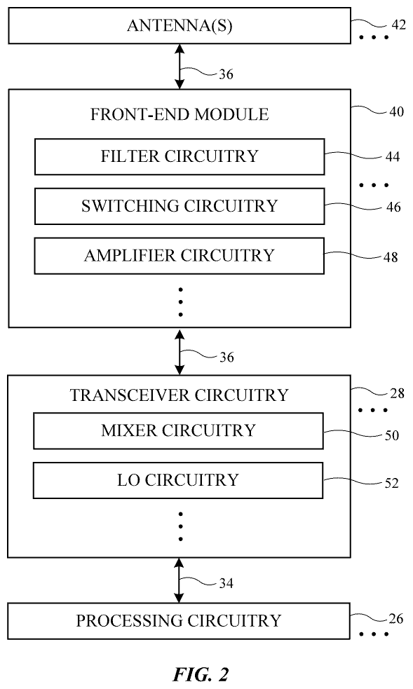

FIG. 2 is a diagram showing illustrative components within wireless circuitry 24. Wireless circuitry 24 can include, as part of oscillator circuitry 52, a phase noise filter with improved phase noise suppression capabilities. As shown in FIG. 2, wireless circuitry 24 may include one or more processors such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may be baseband processing circuitry, one or more application processor, one or more digital signal processor, one or more microcontroller, one or more microprocessor, one or more central processing unit (CPU), one or more programmable device, a combination of these circuits, and/or other types of processors within circuitry 18. Processing circuitry 26 may be configured to generate digital (transmit or baseband) signals. Processing circuitry 26 may be coupled to transceiver 28 over path 34 (sometimes referred to as a baseband path). Transceiver 28 may be coupled to antenna 42 via radio-frequency transmission line path 36. Radio-frequency front-end module 40 may be interposed on radio-frequency transmission line path 36 between transceiver 28 and antenna 42.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

In the example of FIG. 2, wireless circuitry 24 is illustrated as including a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective paths 34. Each transceiver 28 may include a transmitter circuit configured to output uplink signals to antenna 42, may include a receiver circuit configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module interposed thereon.

Front-end module (FEM) 40 may include radio-frequency front-end circuitry that operates on the radio-frequency signals conveyed (transmitted and/or received) over radio-frequency transmission line path 36. Front-end module may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers and one or more low-noise amplifiers), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip.

Filter circuitry 44, switching circuitry 46, amplifier circuitry 48, and other circuitry may be interposed within radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards. In one suitable arrangement, radio-frequency transmission line paths such as radio-frequency transmission line path 36 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHZ WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

In performing wireless transmission, processing circuitry 26 may provide digital signals to transceiver 28 over path 34. Transceiver 28 may further include circuitry for converting the baseband signals received from processing circuitry 26 into corresponding intermediate frequency or radio-frequency signals. For example, transceiver circuitry 28 may include mixer circuitry 50 for up-converting (or modulating) the baseband signals to intermediate frequencies or radio frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may include a transmitter component to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from external wireless equipment. The received radio-frequency signals may be conveyed to transceiver 28 via radio-frequency transmission line path 36 and front-end module 40. Transceiver 28 may include circuitry for converting the received radio-frequency signals into corresponding intermediate frequency or baseband signals. For example, transceiver 28 may use mixer circuitry 50 for downconverting (or demodulating) the received radio-frequency signals to baseband frequencies prior to conveying the received signals to processing circuitry 26 over path 34.

Mixer circuitry 50 can include local oscillator circuitry such as local oscillator (LO) circuitry 52. Local oscillator circuitry 52 can generate oscillator or oscillating signals that mixer circuitry 50 uses to modulate transmitting signals from baseband frequencies to radio frequencies and/or to demodulate the received signals from radio frequencies to baseband or intermediate frequencies. Local oscillator circuitry 52 can generally include phase-locked loop (PLL) circuitry configured to generate the oscillating signals being fed to inputs of mixer circuitry 50.

In practice, phase noise in this local oscillator path can have a direct impact on the signal-to-noise and distortion ratio (SNDR), which, if care is not taken, can degrade the error vector magnitude (EVM) of wireless circuitry 24. As state-of-the-art modulation schemes impose more stringent EVM requirements, the phase noise in the oscillator path can become a dominant factor in the overall link budget. The PLL circuitry can include an oscillator such as a voltage controlled oscillator (VCO). It can be challenging to design a VCO for wireless circuitry 24.

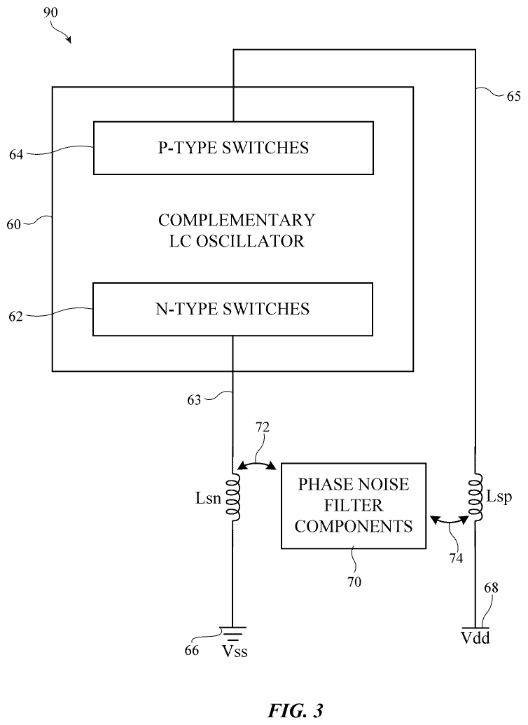

FIG. 3 is a diagram of illustrative oscillator circuitry such as oscillator circuitry 90 having a transformer based phase noise filter in accordance with some embodiments. Oscillator circuitry 90 can represent an oscillator such as a voltage controlled oscillator (VCO) that may be part of a phase-locked loop (PLL) for generating oscillating signals in LO circuitry 52. As shown in FIG. 3, oscillator circuitry 90 may include an oscillator subcircuit 60 that includes inductor (L) and capacitor (C) components and is thus sometimes referred to herein as an “LC” oscillator subcircuit or portion. Oscillator subcircuit 60 may further include n-type switches such as n-type transistors 62 and p-type switches such as p-type transistors 64. Oscillator subcircuit 60 that includes both n-type transistors and p-type transistors is sometimes referred to and defined herein as a “complementary” oscillator subcircuit.

In the example of FIG. 3, the n-type transistors 62 can be coupled to a first tail coil (inductor) such as first tail coil Lsn via connection path 63. The first tail coil Lsn can have a first terminal coupled to the n-type transistors 62 and a second terminal coupled to a ground power supply line 66 (e.g., a ground power supply terminal on which ground voltage Vss is provided). Tail coil Lsn having one side coupled to a power supply line can be referred to as a “single-ended” coil or inductor. On the other end, the p-type transistors 64 can be coupled to another tail coil (inductor) such as second tail coil Lsp via connection path 65. The second tail coil Lsp can have a first terminal coupled to the p-type transistors 64 and a second terminal coupled to a positive power supply line 68 (e.g., a positive power supply terminal on which positive power supply voltage Vdd is provided). Tail coil Lsp having one side coupled to a power supply line can also be referred to as a “single-ended” coil or inductor.

In the example of FIG. 3, one or more phase noise filter components 70 can be magnetically coupled between the first tail coil Lsn and the second tail coil Lsp. For instance, phase noise filter components 70 can include a first filter component that is magnetically coupled to tail coil Lsn (as indicated by arrow 72) and can include a second filter component that is magnetically coupled to tail coil Lsp (as indicated by arrow 74). The tail coils Lsn and Lsp, along with the phase noise filter components 70, can collectively form part of a phase noise filter that is configured to suppress close-in phase (flicker) noise for oscillator circuitry 90. Such phase noise filter that can include the tail coils Lsn and Lsp and filter components 70 can thus sometimes be referred to as a phase noise “tail” filter.

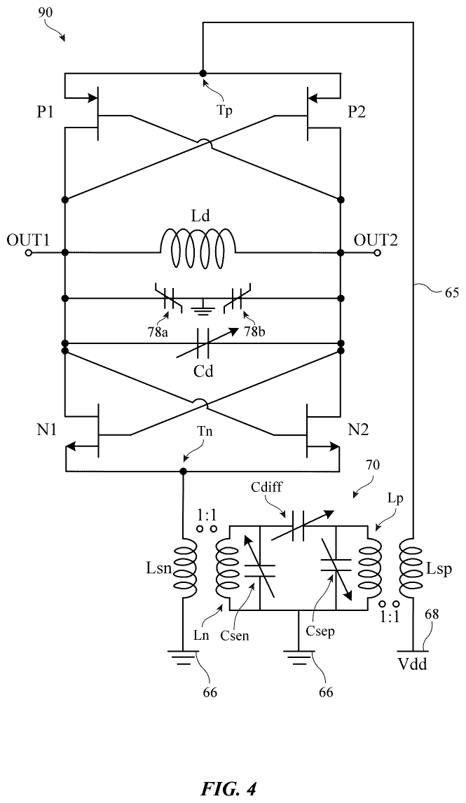

FIG. 4 is a circuit diagram showing an illustrative implementation of complementary oscillator circuitry 90 of the type described in connection with FIG. 3. As shown in FIG. 4, oscillator circuitry 90 can include n-type transistors N1 and N2, p-type transistors P1 and P2, capacitors 78a and 78b, an output capacitor such as tunable load capacitor Cd, an output inductor such as load inductor Ld, and one or more associated coils (inductors) such as tail coils Lsn and Lsp.

Transistors N1 and N2 may be n-type (n-channel) transistors such as n-type metal-oxide-semiconductor (NMOS) devices and can represent the n-type switches 62 shown in FIG. 3. Transistor N1 may have a source terminal coupled to a first tail node such as tail node Tn, a drain terminal coupled to a first output terminal OUT1 of circuitry 90, and a gate terminal that is cross-coupled to a second output terminal OUT2 of circuitry 90. Transistor N2 may have a source terminal coupled to the first tail node Tn, a drain terminal coupled to the second output terminal OUT2, and a gate terminal that is cross-coupled to the first output terminal OUT1. Output terminals OUT1 and OUT2 may serve collectively as a differential output port of oscillator circuitry 90. Oscillating (local oscillator or “LO”) signals can be generated on the differential output port. Transistors N1 and N2 arranged in this way are sometimes referred to as “cross-coupled” differential n-type transistors.

The terms “source” and “drain” terminals used to refer to current-conveying terminals of a transistor may be used interchangeably and are sometimes referred to as “source-drain” terminals. Thus, the source terminal of transistor N1 can sometimes be referred to as a first source-drain terminal, and the drain terminal of transistor N1 can be referred to as a second source-drain terminal (or vice versa). The term “activate” with respect to a switch (or transistor) may refer to or be defined herein as an action that places the switch in an “on” or low-impedance state such that the two terminals of the switch are electrically connected to conduct current. The term “deactivate” with respect to a switch (or transistor) may refer to or be defined herein as an action that places the switch in an “off” or high-impedance state such that the two terminals of the switch/transistor are electrically disconnected with minimal leakage current.

At the other end, transistors P1 and P2 may be p-type (p-channel) transistors such as p-type metal-oxide-semiconductor (PMOS) devices and can represent the p-type switches 64 shown in FIG. 3. Transistor P1 may have a source terminal coupled to a second tail node such as tail node Tp, a drain terminal coupled to the first output terminal OUT1 of circuitry 90, and a gate terminal that is cross-coupled to the second output terminal OUT2 of circuitry 90. Transistor P2 may have a source terminal coupled to the second tail node Tp, a drain terminal coupled to the second output terminal OUT2, and a gate terminal that is cross-coupled to the first output terminal OUT1. Transistors P1 and P2 arranged in this way are sometimes referred to as “cross-coupled” differential p-type transistors.

A first capacitor 78a may have a first terminal coupled to output terminal OUT1 and a second terminal coupled to the ground line. A second capacitor 78b may have a first terminal coupled to output terminal OUT2 and a second terminal coupled to ground. Load (output) inductor Ld may have a first terminal coupled to output terminal OUT1 and a second terminal coupled to output terminal OUT2 (e.g., load inductor Ld may be coupled across the differential output port of oscillator circuitry 90). Tunable load (output) capacitor Cd may have a first terminal coupled to output terminal OUT1 and a second terminal coupled to output terminal OUT2. Load inductor Ld may thus be coupled in parallel with load capacitor Cd. Capacitor Cd may be implemented as a programmable bank of capacitors or other types of adjustable capacitive structure. The first tail coil Lsn may have a first terminal coupled to tail node Tn and a second terminal coupled to ground power supply line 66. The second tail coil Lsp may have a first terminal coupled to tail node Tp and a second terminal coupled to positive power supply line 68.

In the example of FIG. 4, the phase noise filter components can include a first filter coil such as first filter coil Ln, a second filter coil such as second filter coil Lp, a differential capacitor such as tunable differential capacitor Cdiff, a first tunable single-ended capacitor Csen, and a second tunable single-ended capacitor Csep. The first filter coil Ln may be magnetically coupled to first tail coil Lsn. Coils Lsn and Ln may collectively form a first 1:1 (one-to-one) impedance transformer. First filter coil Ln can have a first terminal coupled to differential capacitor Cdiff and a second terminal coupled to ground line 66. A “single-ended” capacitor can refer to and be defined herein as a capacitor having one of its terminals coupled to a static voltage line such as a power supply line. The second filter coil Lp may be magnetically coupled to second tail coil Lsp. Coils Lsp and Lp may collectively form a second 1:1 (one-to-one) impedance transformer. Second filter coil Lp can have a first terminal coupled to differential capacitor Cdiff and a second terminal coupled to ground line 66.

A 1:1 impedance transformer can, as an example, be implemented using a primary coil (winding) and a secondary coil (winding) with overlapping footprints and an identical number of turns and windings to ensure optimum coupling. Not all transformers are 1:1 impedance transformers; transformers having coils that are not substantially overlapping can have different impedance coupling ratios. In particular, the use of 1:1 impedance transformers can be technically advantageous to reduce the sensitivity of the phase noise tail filter to any difficult-to-model power supply routing inductances for minimizing phase noise.

Tunable differential capacitor Cdiff can, for example, be implemented as a bank of switchable capacitors (e.g., an array of capacitors each of which is selectively activated by a respective switch), a variable capacitor sometimes referred to as a varactor, a varicap diode, a metal-oxide-semiconductor capacitor (MOSCAP), and/or other components configured to provide a variable capacitance. Differential capacitor Cdiff can thus sometimes be referred to herein as an adjustable capacitor or a programmable capacitor. Tunable differential capacitor Cdiff can be adjusted by a digital control signal or an analog control signal to trim for minimum phase noise.

The phase noise tail filter is responsible for suppressing phase noise from both the n-type transistors N1 and N2 (i.e., the “n-side” components) and also the p-type transistors P1 and P2 (i.e., the “p-side” components). In practice, however, the condition/impedance for optimal flicker suppression by the phase noise tail filter may be different for the n-side components and the p-side components due to potentially differing characteristics and large signal behavior of the n-type and p-type transistors. For example, the n-type and p-type transistors can have different mobility and conductance values, different threshold voltages, differential parasitics due to process variations, different device parameters that can change as a function of temperature or other operating conditions, and/or other mismatched or unbalanced characteristics.

In accordance with some embodiments, the single-ended capacitors Csen and Csep can be configured as balance restoration components to individually optimize the n-side and p-side impedances for simultaneously minimizing flicker noise contribution from both ends. Capacitor Csen may have a first terminal coupled to a node disposed between coil Ln and capacitor Cdiff and a second terminal coupled to ground 66. In other words, capacitor Csen may be coupled across opposing terminals of coil Ln (e.g., capacitor Csen may be coupled “in parallel” with coil Ln). Capacitor Csep may have a first terminal coupled to a node disposed between coil Lp and capacitor Cdiff and a second terminal coupled to ground 66. In other words, capacitor Csep may be coupled across opposing terminals of coil Lp (e.g., capacitor Csep may be coupled “in parallel” with coil Lp).

Capacitors Csen and Csep can each be implemented as a bank of switchable capacitors (e.g., an array of capacitors each of which is selectively activated by a respective switch), a variable capacitor sometimes referred to as a varactor, a varicap diode, a metal-oxide-semiconductor capacitor (MOSCAP), and/or other components configured to provide a variable capacitance. Capacitors Csen and Csep can thus be referred to herein as tunable capacitors or programmable capacitors. Tunable single-ended capacitors Csen and Csep can be adjusted by digital control signals (e.g., digital codes) or analog control signals (e.g., analog control voltages).

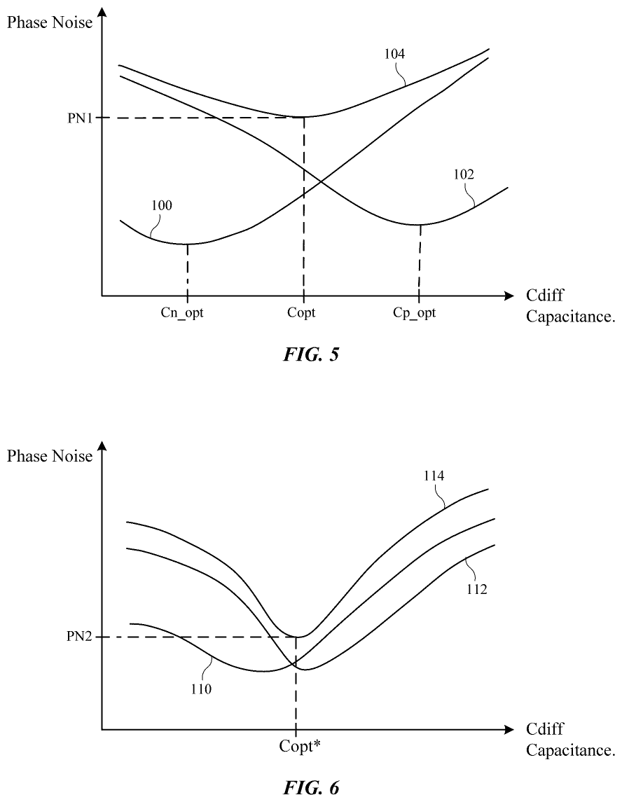

FIG. 5 is a plot of phase noise as a function of differential tail capacitance (i.e., the capacitance of Cdiff) when the n-side and p-side components are unbalanced. Curve 100 represents the phase noise profile for the n-side components (e.g., the n-type transistors), whereas curve 102 represents the phase noise profile for the p-side components (e.g., the p-type transistors). As shown in FIG. 5, curve 100 can exhibit a minimum phase noise when the differential capacitor Cdiff has a capacitance value equal to Cn_opt, whereas curve 102 can exhibit a minimum phase noise when the differential capacitor Cdiff has a capacitance value equal to Cp_opt. Since the optimal Cdiff values for the n-side and p-side are different, the total flicker suppression is limited. Curve 104 represents the total phase noise profile, which sums the contribution from curve 100 and curve 102. Curve 104 can exhibit a minimum phase noise PN1 when differential capacitor Cdiff has a capacitance value equal to Copt, which sits somewhere between Cn_opt and Cp_opt. If care is not taken, Cn_opt and Cp_opt can be substantially offset from each other (e.g., if capacitors Csen and Csep are absent or not optimally tuned). Such offset or misalignment of Cn_opt and Cp_opt can be due to the mismatched characteristics between the n-side and p-side components, which can limit the total flicker suppression capabilities of the phase noise tail filter.

FIG. 6 is a plot of phase noise as a function of differential tail capacitance when the n-side and p-side components are optimized using balance restoring capacitors Csen and Csep to reduce phase noise in accordance with some embodiments. Curve 110 represents the phase noise profile for the n-side components (e.g., the n-type transistors), whereas curve 112 represents the phase noise profile for the p-side components (e.g., the p-type transistors). Curve 114 represents the total phase noise profile, which sums the contribution from curve 110 and curve 112. As shown in FIG. 6, curves 110, 112, and 114 can all exhibit a minimum phase noise when the differential capacitor Cdiff has a capacitance value approximately equal to Copt*. In particular, curve 114 can exhibit a minimum phase noise PN2 that is even less than phase noise PN1 associated with curve 104 of FIG. 5. Here, the alignment of the minimum phase noise can be achieved by tuning the single-ended capacitors Csen and Csep to restore the balance between the n-side and p-side components. Capacitors Csen and Csep operated in this way are therefore sometimes referred to as single-ended tunable/programmable balance restoration (restoring) capacitors. Oscillator circuitry 90 configured in this way is technically advantageous and beneficial by reducing the overall phase noise. The phase noise tail filter configured in this way is thus sometimes referred to as a balance restoring phase noise filter.

Capacitors Csen and Csep should be tuned in a particular way. For instance, when the capacitance of capacitor Csen is increased by a given amount, the capacitance of capacitor Csep should be decreased by the same given amount. Conversely, when the capacitance of capacitor Csen is decreased by a given amount, the capacitance of capacitor Csep should be increased by the same given amount. In other words, the total capacitance of Csen and Csep should be maintained when separately tuning the two balance restoring capacitors.

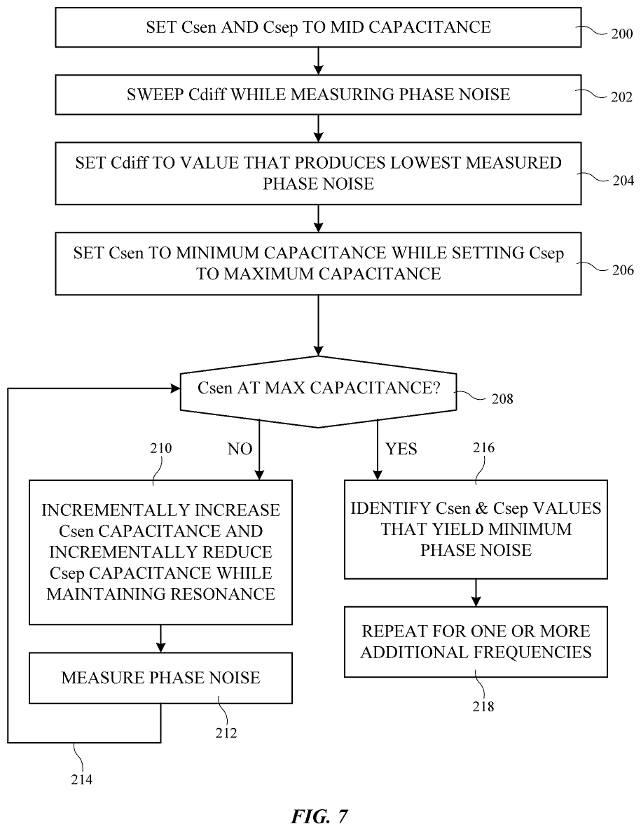

FIG. 7 is a flowchart of illustrative steps for determining capacitance values for a phase noise filter of the type described in connection with at least FIGS. 1-4 and 6. In particular, the operations of the flowchart of FIG. 7 can be performed using control circuitry associated with oscillator 90. The control circuitry can be part of control circuitry 14 (FIG. 1), processing circuitry 18, transceiver circuitry 28 (FIG. 2), processing circuitry 26, or other control circuit on device 10. The operations of FIG. 7 can be performed via simulation, at the factory, and/or during normal user operation.

During the operations of block 200, capacitor Csen and capacitor Csep can each be set to their respective mid capacitance value (e.g., to the midpoint of their variable capacitance range). In the example where capacitors Csen and Csep are each implemented as a bank of switchable capacitors, this can be achieved be selectively deactivating half of the switchable capacitors within each of Csen and Csep while selectively activating the other half of the switchable capacitors within each of Csen and Csep.

During the operations of block 202, the capacitance of differential capacitor Cdiff can be swept while measuring phase noise. For example, the capacitance of capacitor Cdiff can be swept from a minimum (low) Cdiff value to a maximum (high) Cdiff value, or vice versa. The phase noise can be measured at each of the different Cdiff values. In the example where capacitor Cdiff is implemented as a bank of switchable capacitors, this can be achieved by incrementally activating one additional switchable capacitor at a time.

During the operations of block 204, the capacitance of differential capacitor Cdiff can be set to a value that produces the lowest (minimum) phase noise measured during the operations of block 202. After this point, the value of Cdiff can remain fixed at this optimum Cdiff value. Subsequently at block 206, capacitor Csen can be set to a minimum (low) capacitance while capacitor Csep is set to a maximum (high) capacitance. In the example where capacitors Csen and Csep are each implemented as a bank of switchable capacitors, this can be achieved by selectively deactivating all of the switchable capacitors within capacitor Csen while selectively activating all of the switchable capacitors within capacitor Csep. This example where capacitor Csen is initially configured with the minimum capacitance is merely illustrative. Alternatively, capacitor Csen can be initially set to the maximum capacitance while capacitor Csep is initially set to the minimum capacitance during the operations of block 200.

The control circuitry can then determine whether Csen has reached the maximum capacitance (see operations of block 208). If Csen has not yet reached its maximum capacitance, then the control circuitry can incrementally increase the Csen capacitance while incrementally decreasing the Csep capacitance to maintain the overall capacitance, as shown by the operations of block 210. For example, one additional switchable capacitor within Csen can be activated, whereas one switchable capacitor within Csep can be deactivated. Maintaining the overall capacitance in this way can help ensure that the phase noise tail filter exhibits a constant resonant frequency. Thereafter, a corresponding phase noise can be measured, as shown by the operations of block 212. Processing can then loop back to block 208, as indicated by path 214.

If the control circuitry determines at block 208 that capacitor Csen has reached its maximum capacitance, then the control circuitry can identify a pair of Csen and Csep values (e.g., a pair of values measured during an instance of block 210) that yield the minimum phase noise, as shown by the operations of block 216. It is possible for the capacitances of capacitors Csen and Csep to be equal. However, it is more likely that the capacitance of Csep is different than the capacitance of Csen to achieve the balance restoration of the n-side and p-side components. The end result may produce optimal phase noise profiles of the kind described in connection with FIG. 6.

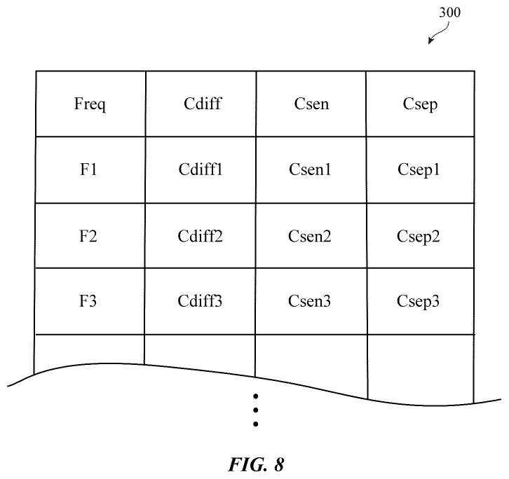

The operations of block 200-216 can optionally be repeated for different operating frequencies, as indicated by block 218. In other words, for each operating frequency, the optimal Cdiff, Csen, and Csep values determined using the steps of FIG. 7 can be different. FIG. 8 is a table 300 of illustrative capacitance values for a phase noise filter configured to operate at various frequencies. As shown in FIG. 8, when oscillator 90 is configured to operate at a first frequency F1 (or a first range of frequencies), capacitors Cdiff, Csen, and Csep can be set to values Cdiff1, Csen1, and Csep1, respectively, to minimize phase noise.

When oscillator 90 is configured to operate at a second frequency F2 (or a second range of frequencies) different than F1, capacitors Cdiff, Csen, and Csep can be set to values Cdiff2, Csen2, and Csep2, respectively, to minimize phase noise—where Cdiff2 can be different than Cdiff1, where Csen2 can be different than Csen1, and where Csep2 can be different than Csep1. When oscillator 90 is configured to operate at a third frequency F3 (or a third range of frequencies) different than F1 and F2, capacitors Cdiff, Csen, and Csep can be set to values Cdiff3, Csen3, and Csep3, respectively, to minimize phase noise—where Cdiff3 can be different than Cdiff1 or Cdiff2, where Csen3 can be different than Csen1 or Csen2, and where Csep3 can be different than Csep1 or Csep2. Table 300 can be stored as a lookup table (LUT) on device 10. In general, lookup table 300 can include a list of optimal capacitance values for the phase noise tail filter for two or more frequencies, two to ten different frequencies, more than ten different frequencies, 10 to 100 different frequencies, more than 100 different frequencies, any number of frequency ranges, any number of frequency bands, etc.

The operations of FIG. 7 are illustrative. In some embodiments, one or more of the described operations may be modified, replaced, or omitted. In some embodiments, one or more of the described operations may be performed in parallel. In some embodiments, additional processes may be added or inserted between the described operations. If desired, the order of certain operations may be reversed or altered and/or the timing of the described operations may be adjusted so that they occur at slightly different times. In some embodiments, the described operations may be distributed in a larger system.

The methods and operations described above in connection with FIGS. 1-8 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Oscillator circuitry comprising:
a pair of n-type transistors coupled to a first tail node;
a pair of p-type transistors coupled to a second tail node;
output terminals coupled between the pair of n-type transistors and the pair of p-type transistors and configured to provide an oscillating signal;
a first tail coil coupled to the first tail node;
a first filter coil magnetically coupled to the first tail coil; and
a first tunable capacitor coupled across opposing terminals of the first filter coil.

2. The oscillator circuitry of claim 1, further comprising:
a second tail coil coupled to the second tail node; and
a second filter coil magnetically coupled to the second tail coil.

3. The oscillator circuitry of claim 2, further comprising:
a second tunable capacitor coupled across opposing terminals of the second filter coil.

4. The oscillator circuitry of claim 3, further comprising:
a tunable differential capacitor coupled between the first tunable capacitor and the second tunable capacitor.

5. The oscillator circuitry of claim 4, wherein:
a first of the opposing terminals of the first filter coil is coupled to the tunable differential capacitor; and
a second of the opposing terminals of the first filter coil is coupled to a power supply line.

6. The oscillator circuitry of claim 5, wherein:
a first of the opposing terminals of the second filter coil is coupled to the tunable differential capacitor; and
a second of the opposing terminals of the second filter coil is coupled to the power supply line.

7. The oscillator circuitry of claim 3, wherein:
the first tunable capacitor is configured to provide a first capacitance value; and
the second tunable capacitor is configured to provide a second capacitance value different than the first capacitance value.

8. The oscillator circuitry of claim 3, wherein:
when the oscillator circuitry is configured to operate at a first frequency, the tunable differential capacitor, the first tunable capacitor, and the second tunable capacitor are adjusted to a first set of capacitance values optimized for reducing phase noise at the first frequency; and
when the oscillator circuitry is configured to operate at a second frequency different than the first frequency, the tunable differential capacitor, the first tunable capacitor, and the second tunable capacitor are adjusted to a second set of capacitance values, different than the first set of capacitance values, optimized for reducing phase noise at the second frequency.

9. The oscillator circuitry of claim 1, further comprising:
a load inductor coupled across the output terminals; and
a load capacitor coupled across the output terminals.

10. The oscillator circuitry of claim 1, wherein the first tail coil and the first filter coil comprise a one-to-one impedance transformer.

11. Oscillator circuitry comprising:
a pair of cross-coupled n-type transistors coupled to a first tail node;
a pair of cross-coupled p-type transistors coupled to a second tail node;
a first 1:1 impedance transformer coupled to the first tail node; and
a first tunable single-ended capacitor coupled to the first 1:1 impedance transformer.

12. The oscillator circuitry of claim 11, further comprising:
a second 1:1 impedance transformer coupled to the second tail node; and
a second tunable single-ended capacitor coupled to the second 1:1 impedance transformer.

13. The oscillator circuitry of claim 12, wherein:
the first 1:1 impedance transformer comprises a first tail coil coupled to the first tail node and a first filter coil coupled magnetically coupled to the first tail coil; and
the second 1:1 impedance transformer comprises a second tail coil coupled to the second tail node and a second filter coil coupled magnetically coupled to the second tail coil.

14. The oscillator circuitry of claim 12, further comprising:
a tunable differential capacitor having a first terminal coupled to the first tunable single-ended capacitor and having a second terminal coupled to the second tunable single-ended capacitor.

15. The oscillator circuitry of claim 12, wherein the pair of cross-coupled n-type transistors and the pair of cross-coupled p-type transistors exhibit unbalanced characteristics, and wherein the first tunable single-ended capacitor and second tunable single-ended capacitors are configured to restore a balance between the pair of cross-coupled n-type transistors and the pair of cross-coupled p-type transistors.

16. Circuitry comprising:
a pair of n-type transistors coupled to a first tail node;
a pair of p-type transistors coupled to a second tail node, wherein the pair of n-type transistors and the pair of p-type transistors exhibit unbalanced characteristics;
a load inductor coupled between the pair of n-type transistors and the pair of p-type transistors;
a load capacitor coupled in parallel with the load inductor; and
a phase noise filter configured to reduce a phase noise of the circuitry and coupled between the first and second tail nodes, wherein the phase noise filter comprises at least first and second single-ended capacitors configured to restore a balance between the pair of n-type transistors and pair of p-type transistors.

17. The circuitry of claim 16, wherein the phase noise filter further comprises:
a first coil coupled in parallel with the first single-ended capacitor; and
a second coil coupled in parallel with the second single-ended capacitor.

18. The circuitry of claim 17, wherein the phase noise filter further comprises:
a third coil coupled to the first tail node and magnetically coupled to the first coil; and
a fourth coil coupled to the second tail node and magnetically coupled to the second coil.

19. The circuitry of claim 18, wherein the phase noise filter further comprises:
a differential capacitor having a first terminal coupled to a node between the first coil and the first single-ended capacitor and having a second terminal coupled to a node between the second coil and the second single-ended capacitor.

20. The circuitry of claim 18, wherein:
the first coil and the third coil are part of a first 1:1 impedance transformer with identical and overlapping footprints;
the second coil and the fourth coil are part of a second 1:1 impedance transformer with identical and overlapping footprints; and
the first and second single-ended capacitors have different capacitance values.
